(19) United States
(12) Patent Application Publication
(10) Pub. No.: US 2026/0009128 A1
(43) Pub. Date: Jan. 8, 2026

(54) GAS INJECTION SYSTEM AND REACTOR SYSTEM INCLUDING SAME

(71) Applicant: ASM IP Holding B.V., Almere (NL)

(72) Inventors: Tomas Hernandez Acosta, Phoenix, AZ (US); Alexandros Demos, Scottsdale, AZ (US); Peter Westrom, Phoenix, AZ (US); Caleb Miskin, Mesa, AZ (US); Amir Kajbafvala, Chandler, AZ (US); Ali Moballegh, Chandler, AZ (US)

(21) Appl. No.: 19/324,553

(22) Filed: Sep. 10, 2025

Related U.S. Application Data
(63) Continuation of application No. 17/060,764, filed on Oct. 1, 2020, now Pat. No. 12,428,726.
(60) Provisional application No. 62/912,521, filed on Oct. 8, 2019.

(51) Int. Cl. C23C 16/455; B01J 4/00; C23C 16/46; C23C 16/52

(52) U.S. Cl. CPC C23C 16/45502; B01J 4/008; C23C 16/45544; C23C 16/45553; C23C 16/46; C23C 16/52

(57) ABSTRACT

A gas injection system, a reactor system including the gas injection system, and methods of using the gas injection system and reactor system are disclosed. The gas injection system can be used in gas-phase reactor systems to independently monitor and control gas flow rates in a plurality of channels of a gas injection system coupled to a reaction chamber.

### CROSS-REFERENCE TO RELATED APPLICATIONS

This application is a continuation of, and claims priority to and the benefit of, U.S. patent application Ser. No. 17/060,764, filed Oct. 1, 2020 and entitled “GAS INJECTION SYSTEM AND REACTOR SYSTEM INCLUDING SAME,” which is a nonprovisional of, and claims priority to and the benefit of, U.S. Provisional Patent Application No. 62/912,521, filed Oct. 8, 2019 and entitled “GAS INJECTION SYSTEM AND REACTOR SYSTEM INCLUDING SAME,” all of which are hereby incorporated by reference herein.

### FIELD OF THE DISCLOSURE

The present disclosure generally relates to gas-phase reactors and systems. More particularly, the disclosure relates to gas injection systems for introducing gas to a reaction chamber, to reactors and reactor systems including a gas injection system, and to methods of using same.

### BACKGROUND OF THE DISCLOSURE

Gas-phase reactors, such as chemical vapor deposition (CVD), plasma-enhanced CVD (PECVD), and atomic layer deposition (ALD) reactors can be used for a variety of applications, including depositing and etching materials on a substrate surface and/or cleaning a substrate surface. For example, gas-phase reactors can be used to deposit and/or etch layers on a substrate to form semiconductor devices, flat panel display devices, photovoltaic devices, microelectromechanical systems (MEMS), and the like.

A typical gas-phase reactor system includes a reactor including a reaction chamber, one or more precursor and/or reactant gas sources fluidly coupled to the reaction chamber, one or more carrier and/or purge gas sources fluidly coupled to the reaction chamber, a gas injection system to deliver gases (e.g., precursor/reactant gas(es) and/or carrier/purge gas(es)) to the reaction chamber, and an exhaust source fluidly coupled to the reaction chamber.

Generally, it is desirable to have uniform film properties (e.g., film thickness and film composition) across a surface of a substrate and/or to have control over any desired variation of the film properties. As sizes of features formed on a substrate surface decrease, it becomes increasingly important to control film properties, such as film thickness, composition, and resistivity. Moreover, it may be desirable to independently tune film properties; e.g., to independently tune film thickness uniformity and/or composition in layers deposited using gas-phase reactors, such as epitaxial layers grown using such reactors. Accordingly, gas injection systems, reactor systems including the gas injection systems, and methods of using the gas injection and reactor systems, which allow for desired control and manipulation of parameters that lead to desired film properties, are desired.

Any discussion, including discussion of problems and solutions, set forth in this section has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Various embodiments of the present disclosure relate to gas injection systems, reactor systems including a gas injection system, and to methods of using the gas injection systems and reactor systems. While the ways in which various embodiments of the present disclosure address drawbacks of prior gas injection systems and reactor systems are discussed in more detail below, in general, various embodiments of the disclosure provide gas injection systems that can provide improved control of film thickness and/or film composition across a surface of a substrate. As set forth in more detail below, examples of the disclosure may be particularly useful for forming doped epitaxial layers on a surface of a substrate. Exemplary systems and methods can allow fine tuning of precursor and dopant flowrates to a reaction chamber and/or a substrate surface to allow formation of films with desired thickness and/or composition uniformity and/or variation. For example, in some cases, it may be desirable to form films with desired composition variation-rather than to form a film with uniform composition across a substrate surface.

In accordance with exemplary embodiments of the disclosure, a gas injection system includes a first gas manifold comprising a first gas inlet and a plurality of first gas outlets; a second gas manifold comprising a second gas inlet and a plurality of second gas outlets; a plurality of first gas valves, wherein each of the plurality of first gas outlets is coupled to at least one of the plurality of first gas valves; and a plurality of second gas valves, wherein each of the plurality of second gas outlets is coupled to at least one of the plurality of second gas valves. The first gas inlet can receive a first gas comprising a first precursor and a dopant. The second gas inlet can receive a second gas comprising the first precursor or a second precursor and an etchant. In accordance with some examples of the disclosure, the second gas includes the first precursor. A chemical formula of the first precursor and a chemical formula of the second precursor can comprise one or more or all of the same elements. The gas injection system can further include a first flow controller coupled to a first precursor source and the first gas inlet and a second flow controller coupled to the first precursor source and the second gas inlet.

In accordance with additional embodiments of the disclosure, a gas injection system includes a first gas manifold comprising a first gas inlet and a plurality of first gas outlets; a second gas manifold comprising a second gas inlet and a plurality of second gas outlets; a plurality of first gas valves, wherein each of the plurality of first gas outlets is coupled to at least one of the plurality of first gas valves; and a plurality of second gas valves, wherein each of the plurality of second gas outlets is coupled to at least one of the plurality of second gas valves, wherein the first gas inlet receives a first gas comprising an etchant and a dopant. The second gas inlet can receive a second gas comprising a precursor. The first and/or second gas can include a carrier gas. The gas injection system can include a flow controller to control a flowrate of a carrier gas to the first and/or second gas inlet.

In accordance with additional exemplary embodiments of the disclosure, a gas-phase reactor system includes one or more gas injection systems as described herein. Exemplary systems can also include an exhaust (e.g., vacuum) source coupled to the reaction chamber, a first gas source fluidly coupled to the one or more first gas channels, and a second gas source fluidly coupled to the one or more second gas channels. Exemplary systems can also include additional gas and/or exhaust sources.

In accordance with yet additional exemplary embodiments of the disclosure, a method is provided. Exemplary methods include depositing material on a surface of a substrate using a gas injection system and/or a reactor system as described herein. Exemplary methods can include automatically adjusting one or more valves coupled to the one or more first gas outlets and/or automatically adjusting one or more valves coupled to the one or more second gas outlets. Exemplary methods can also include a step of providing an asymmetric setting of one or more of a first gas from the first gas source and a second gas from the second gas source—to, e.g., tune (e.g., independently) film properties, such as film thickness, film thickness uniformity, and film composition across a surface of a substrate, including an edge region of the substrate, and the like. In accordance with some examples, a method includes a step of rotating a susceptor at a rotational speed of about 60 to about 30, or about 30 to about 15, or about 15 to about 5 rotations per minute.

These and other embodiments will become readily apparent to those skilled in the art from the following detailed description of certain embodiments having reference to the attached figures; the disclosure not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a reactor system in accordance with at least one exemplary embodiment of the present disclosure.

FIG. 2 schematically illustrates a gas injection system in accordance with at least one exemplary embodiment of the disclosure.

FIG. 3 illustrates a cross-sectional view of a flange in accordance with at least one exemplary embodiment of the disclosure.

FIG. 4 schematically illustrates a portion of a reactor system in accordance with at least one exemplary embodiment of the disclosure.

FIGS. 5A and 5B illustrate charts depicting characteristics of silicon germanium layers deposited on a substrate in accordance with at least one exemplary embodiment of the disclosure.

FIG. 6 illustrates charts depicting characteristics of another silicon germanium layer deposited on a substrate in accordance with at least one exemplary embodiment of the disclosure.

It will be appreciated that elements in the figures are illustrated for simplicity and clarity and have not necessarily been drawn to scale. For example, the dimensions of some of the elements in the figures may be exaggerated relative to other elements to help to improve the understanding of illustrated embodiments of the present disclosure.

### DETAILED DESCRIPTION OF EXEMPLARY EMBODIMENTS OF THE DISCLOSURE

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features.

The present disclosure generally relates to gas injection systems, to reactors and reactor systems including a gas injection system, and to methods of using the gas injection systems and reactor systems. Gas injection systems, reactors, and reactor systems including a gas injection system as described herein, can be used to process substrates, such as semiconductor wafers. By way of examples, the systems described herein can be used to form or grow epitaxial layers (e.g., two-component and/or doped semiconductor layers) on a surface of a substrate. Exemplary systems can be further used to provide etch chemistry to a substrate surface. For example, exemplary systems can provide a mixture of two or more gases (e.g., collectively referred to herein as a mixture or simply gas or first gas or second gas) during a deposition (e.g., growth) process. For example, a first gas can include a first precursor and/or a dopant, and a second gas can include the first precursor and/or a second precursor and/or an etchant, or a first gas can include an etchant and/or a dopant, and a second gas can include a precursor. The etchant can be used to facilitate desired film deposition and/or to facilitate selective deposition of the film overlying a first material/surface on a substrate surface relative to deposition of the film overlying a second material/surface of the substrate. Exemplary gas injection systems, reactor systems, and methods described herein, may be particularly useful in forming films having relatively high dopant concentrations (e.g., greater than about 30 percent, about 20 percent or about 10 percent).

As set forth in more detail below, use of exemplary gas injection systems as described herein is advantageous, because it allows independent metering and control of gas (e.g., a gas mixture) flow through various channels of the gas injection systems, and, in turn, to input sites of a reaction chamber. The independent control of gas flow can, in turn, allow independent tuning of film properties of films that are formed using a reactor system including the gas injection system. For example, an exemplary gas injection system can be used to independently tune dopant concentration profiles and film thickness (or thickness uniformity) of, for example, epitaxially formed layers on a substrate. Additionally or alternatively, exemplary gas injection systems can be used to compensate for gas flow variations, depletion rate variations, auto doping, variations in dopant profiles that might otherwise occur because of features on a substrate surface, or combinations thereof that may otherwise occur within a reaction chamber of a reactor system. For example, the independent gas flow control at various input sites can be used to compensate for, or mitigate against, undesired edge effects (e.g., to mitigate against edge roll-down, i.e., a decrease in the rate of layer thickness increase toward the edge of a substrate) and/or undesired effects of a rotating substrate, which might otherwise cause undesired nonuniformity or other characteristics in one or more film properties. Exemplary gas injection systems are scalable to any desired number of channels and can be used with gas mixtures, while maintaining desired precision and control of flow rates (e.g., independent of the makeup of the gas mixture). Additionally, exemplary gas injection systems of the present disclosure can be used for relatively high gas flow rates (e.g., greater than five standard liters per minute of nitrogen through each channel) and/or can operate at relatively high (e.g., near atmospheric) pressures, if desired. These and other features of the systems and methods described herein can be particularly useful in depositing high-quality epitaxial layers on substrates.

As used herein, the terms precursor and/or reactant can refer to one or more gases/vapors that take part in a chemical reaction or from which a gas-phase substance that takes part in a reaction is derived. The chemical reaction can take place in the gas phase and/or between a gas phase and a surface of a substrate and/or a species on a surface of a substrate.

As used herein, a substrate can refer to any material having a surface onto which material can be deposited. A substrate can include a bulk material such as silicon (e.g., single crystal silicon) or may include one or more layers overlying the bulk material. Further, the substrate may include various topologies, such as trenches, vias, lines, and the like formed within or on at least a portion of a layer of the substrate.

As used herein, the term epitaxial layer can refer to a substantially single crystalline layer upon an underlying substantially single crystalline substrate or layer.

As used herein, the term chemical vapor deposition can refer to any process wherein a substrate is exposed to one or more gas-phase precursors, which react and/or decompose on a substrate surface to produce a desired deposition.

As used herein, the terms film and/or layer can refer to any continuous or non-continuous structures and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

As used herein, the term structure can refer to a substrate as described herein, and/or a substrate including one or more layers overlying the substrate, such as one or more layers formed according to a method as described herein.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

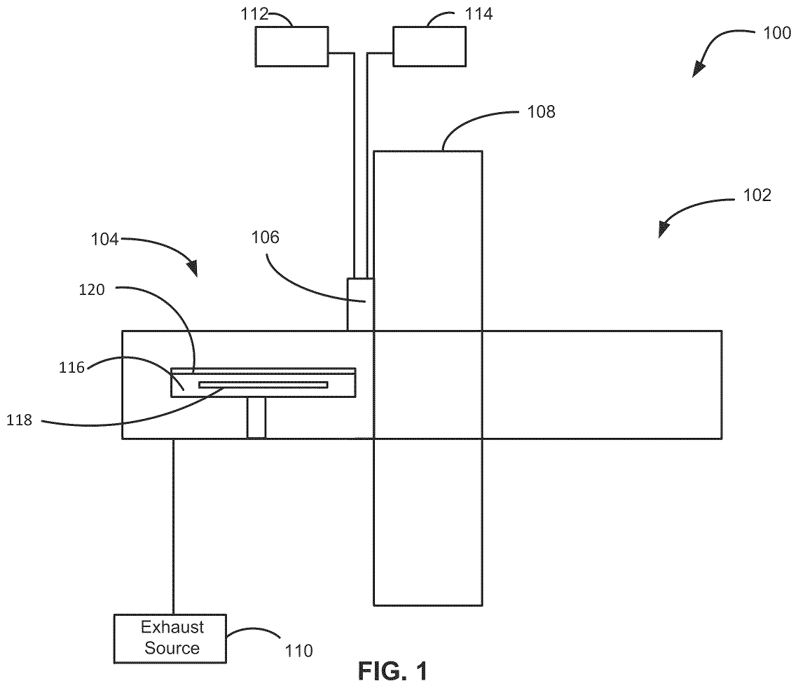

Turning now to the figures, FIG. 1 illustrates an exemplary reactor system 100. Reactor system 100 can be used for a variety of applications, such as, for example, chemical vapor deposition (CVD), plasma-enhanced CVD (PECVD), atomic layer deposition (ALD), clean processes, etch processes, and the like. Although exemplary embodiments are described below in connection with epitaxial reactor systems, embodiments and the disclosure are not so limited, unless stated otherwise.

In the illustrated example, reactor system 100 includes an optional substrate handling system 102, a reaction chamber 104, a gas injection system 106, and optionally a wall 108 disposed between reaction chamber 104 and substrate handling system 102. System 100 can also include a first gas source 112, a second gas source 114, an exhaust source 110, and a susceptor or substrate support 116. Although illustrated with two gas sources 112, 114, reactor system 100 can include any suitable number of gas sources. Further, reactor system 100 can include any suitable number of reaction chambers 104, which can each be coupled to a gas injection system 106. In the case in which reactor system 100 includes multiple reaction chambers, each gas injection system can be coupled to the same gas sources 112, 114 or to different gas sources.

Gas sources 112, 114 can include a compound or a combination of compounds for delivery to reaction chamber 104. For example, gas sources 112, 114 can include various combinations of one or more precursors, one or more dopant sources, one or more etchants, and mixtures of gases, including mixtures of one or more precursors, dopant sources, and/or etchants with one or more carrier gases.

By way of examples, first gas source 112 can include an etchant and a dopant source. Second gas source 114 can include a precursor. Alternatively, first gas source 112 can include an etchant and a dopant source; second gas source 114 can include a precursor. As another example, first gas source 112 can include a first precursor, a second precursor, and/or an etchant, and the second gas source 114 can include the first precursor and/or an etchant. The etchant comprised in first gas source 112 and second gas source 114 may be the same compound. In various embodiments, first gas source 112 and second gas source 114 may have at least one component (e.g., a precursor, etchant, etc.) in common.

Exemplary etchants can include a halide, such as a chlorine-containing gas. Exemplary chlorine-containing gases include one or more gases selected from the group consisting of hydrogen chloride, chlorine gas, and the like.

Exemplary precursors include silicon-containing precursors, such as trichlorosilane, dichlorosilane, silane, disilane, trisilane, silicon tetrachloride, and the like, and/or germanium-containing precursors, such as germane (GeH₄), digermane (Ge₂H₆), trigermane (Ge₃H₈), and the like.

Exemplary dopant sources include gases that include one or more of As, P, C, Ge, and B. By way of examples, the dopant source can include germane, diborane, phosphine, arsine, phosphorus trichloride. The gas injection systems, reactor systems, and methods described herein may be particularly useful in forming p-type doped films, such as p-type doped films comprising silicon, silicon germanium, or the like.

Carrier gases can be or include one or more inert gases and/or hydrogen. Exemplary carrier gases include one or more gases selected from the group consisting of hydrogen, nitrogen, argon, helium, or the like.

When the first gas includes a first precursor and a dopant source, the first gas can include from about 30 to about 5 or about 15 to about 5 volumetric percent first precursor and/or from about 15 to about 5 or about 10 to about 5 volumetric percent dopant source. First gas source can also include from about 75 to about 95 or about 85 to about 90 volumetric percent carrier gas.

When the first gas includes an etchant and a dopant source, the first gas can include from about 25 to about 5, about 20 to about 5, or about 15 to about 5 volumetric percent etchant and/or from about 25 to about 5, about 20 to about 5, or about 15 to about 5 volumetric percent dopant source. First gas source can also include from about 60 to about 95, about 70 to about 90, or about 75 to about 85 volumetric percent carrier gas.

When the second gas includes the first precursor and/or a second precursor and an etchant, the first gas can include from about 0 to about 20 or about 5 to about 15 volumetric percent first and/or second precursor and/or from about 0 to about 7 or about 2 to about 5 volumetric percent etchant. Second gas source can also include from about 75 to about 95 or about 85 to about 95 volumetric percent carrier gas.

When the second gas includes a precursor, the first gas can include from about 5 to about 20 or about 5 to about 15 volumetric percent precursor. Second gas source can also include from about 75 to about 95 or about 85 to about 95 volumetric percent carrier gas.

Reactor system 100 can include any suitable number of reaction chambers 104 and substrate handling systems 102. Reaction chamber 104 of reactor system 100 can be or include, for example, a cross flow, cold wall epitaxial reaction chamber.

Susceptor or substrate support 116 can include one or more heaters 118 to heat a substrate 120—e.g., to a temperature of about 500 to about 600, about 600 to about 700, or about 700 to about 800 degrees Celsius. Susceptor or substrate support 116 can also be configured to rotate during processing. In accordance with examples of the disclosure, susceptor or substrate support 116 rotates at a speed of about 60 to about 30, about 30 to about 15, or about 15 to about 5 rotations per minute.

During operation of reactor system 100, substrates 120, such as semiconductor wafers, are transferred from, e.g., substrate handling system 102, to reaction chamber 104. Once substrate(s) 120 are transferred to reaction chamber 104, one or more gases from first and second gas sources 112, 114, such as precursors, dopants, carrier gases, etchants, and/or purge gases are introduced into reaction chamber 104 via gas injection system 106. As set forth in more detail below, gas injection system 106 can be used to meter and control gas flow of one or more gases from first gas source 112 and second gas source 114 during substrate processing and to provide desired flows of such gas(es) to multiple sites within reaction chamber 104.

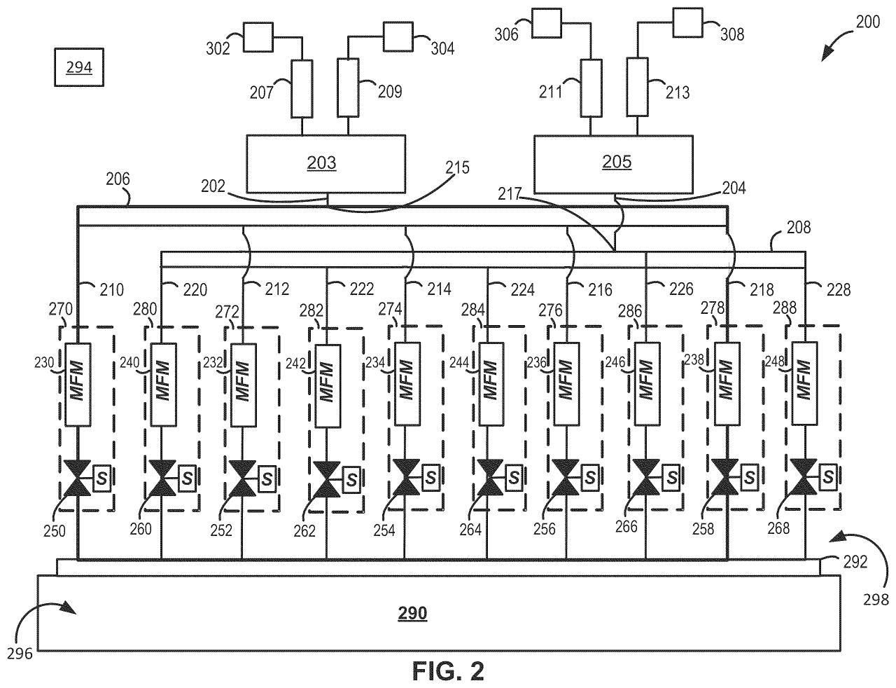

FIG. 2 schematically illustrates a gas injection system 200, suitable for use as gas injection system 106, in accordance with exemplary embodiments of the disclosure. Gas injection system 200 includes a first gas supply line 202 coupled to a first gas source 203, which can be the same or similar to gas source 112, and a second gas supply line 204 coupled to a second gas source 205, which can be the same or similar to gas source 114. When referring to gas lines and fluid components of gas injection system 200, the term coupled refers to fluidly coupled, and, unless stated otherwise, the lines or components need not be directly fluidly coupled, but rather gas injection system 200 can include other intervening elements, such as connectors, valves, meters, or the like.

Gas injection system 200 includes a first gas manifold 206 coupled to first gas supply line 202 via a first gas inlet 215 and a second gas manifold 208 coupled to second gas supply line 204 via a second gas inlet 217. First gas manifold 206 includes a plurality of first gas outlets 210-218. Similarly, second gas manifold 208 includes a plurality of second gas outlets 220-228. First gas manifold 206 and second gas manifold 208 are configured to receive gas from one or more gas lines (e.g., first and second gas lines 202, 204) and distribute the gas into one or more channels, which are respectively defined, in part, by first gas outlets 208-218 and second gas outlets 220-228. In the illustrated example, each of the first and second gas streams from first gas source 203 and second gas source 205 is divided into five gas channels. Although illustrated with five of each of first gas outlets 208-218 and second gas outlets 220-228, gas injection systems in accordance with this disclosure can include any suitable number of first, second, and/or other gas outlets, corresponding to a number of channels for the respective gases. For example, exemplary systems can include, for example, about 1-10 channels or include 5, 6, 7, 9, or more channels for each gas. As illustrated, first gas manifold 206 and/or second gas manifold 208 can include a loop configuration to facilitate even flow distribution through the gas channels. Additionally or alternatively, first gas manifold 206 and/or second gas manifold 208 can have a relatively large diameter relative to gas lines 202, 204—e.g., the diameter of first gas manifold 206 and/or second gas manifold 208 can be greater than 2, 3, 4, or 5 times larger than the diameter of line 202 and/or line 204. In the illustrated examples, first gas channels and second gas channels are alternatingly adjacent each other. However, this need not be the case.

As noted above, first gas source 203 and/or second gas source 205 can be a mixture of two or more gases. In such cases, one or more gases, which may, in turn, include a mixture of gases—or not, can be supplied from other sources (not illustrated) to first gas source 203 and/or second gas source 205 via flow controllers 207-213 (e.g., first gas source 203 is coupled to first flow controllers 207-209 and second gas source 205 is coupled to second flow controllers 211-213). When the source gases upstream of flow controllers 207-213 are not mixtures of gases, flow controllers 207-213 can suitably be mass flow controllers. By way of examples, one or more of flow controllers 207-213 can control a flow rate of a carrier gas to first gas source 203 and/or second gas source 205. Flow controllers 207-213 can be coupled to upstream gas sources 302-308 (e.g., first flow controllers 207-209 are coupled to first upstream gas sources 302-304 and second flow controllers 211-213 are coupled to second upstream gas sources 306-308), described in more detail below.

Gas injection system 200 additionally includes a plurality of flow sensors 230-248 coupled to first and second gas outlets 210-228. In the illustrated example, each first and second gas outlets 210-228 is coupled to a single flow sensor 230-248. However, in some cases, it may be desirable to have some gas outlets that are not coupled to a flow sensor and/or to have some gas outlets that are coupled to more than one flow sensor.

Flow sensors 230-248 can be used to monitor flow rates of gas mixtures and to provide real-time and/or historical flow rate information to a user for each channel—e.g., using a graphical user interface. Additionally or alternatively, flow sensors 230-248 can be coupled to a controller (e.g., controller 294) and to gas valves 250-268 to provide controlled flow ratio of the gases through gas valves 250-268. By placing at least one flow sensor 230-248 in each gas channel, the flow ratio (e.g., relative flow rate) of gas through each channel can be measured and controlled, regardless of the gas composition. Exemplary flow sensors 230-248 can be or include various flow sensors, e.g., thermal mass flow sensors, pressure drop based flow sensors, or the like.

Gas valves 250-268 (e.g., first gas valves 250-258 in fluid communication with first gas source 203 and second gas valves 260-268 in fluid communication with second gas source 205) may allow the control of gas flow through one or more gas outlets 210-228 (e.g., each flow rate through gas outlets 210-228 may be individually controlled, or groups of gas outlets may be controlled, such as all gas outlets coupled to first gas manifold 206 and first gas source 203, or to second gas manifold 208 and second gas source 205). Gas valves 250-268 can include any suitable device to meter flow of a gas. In accordance with various embodiments of the disclosure, gas valves 250-268 each comprise proportional valves, such as solenoid valves, pneumatic valves, or piezoelectric valves. A valve with a relatively high (e.g., 0.021-0.14) flow coefficient (Cv) may be selected to reduce chocking downstream. Gas valves 250-268 may desirably operate under closed-loop control, but may also be capable (e.g., additionally) of operating under open-loop control.

Flow sensors 230-248 and gas valves 250-268 can initially form part of, for example, a mass flow controller (e.g., an off-the-shelf mass flow controller), wherein the control function of the valve is replaced by controller 294. For example, flow meter 230 and gas valve 250 can form or be part of a mass flow controller 270 that is set to operate in open-loop mode and wherein controller 294 provides closed-loop control of valves 250-268. Flow sensors 232-248 and gas valves 252-268 can similarly form or be part of a mass flow controller 272-288. This configuration allows for implementation in standard reactor configurations and/or for use of readily-available mass flow controllers and flow sensors and valves.

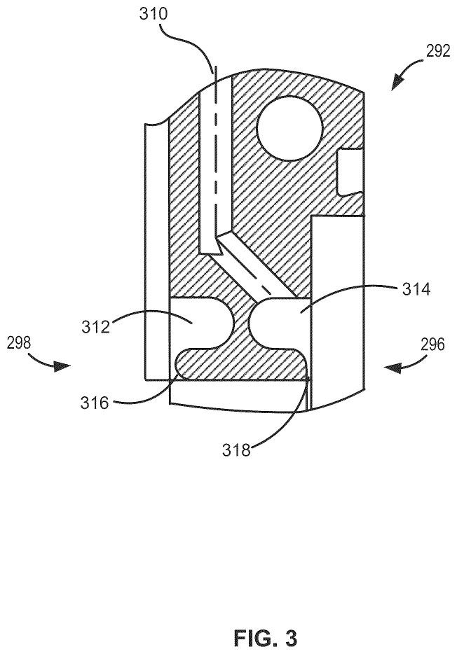

Gas valves 250-268 can be coupled to a reaction chamber 290 via a flange 292. Additional line (e.g., tubing) and suitable connectors can be used to couple gas valves 250-268 to flange 292. Exemplary flange 292 includes flange gas channels to maintain the channels until the respective gases exit into reaction chamber 290; one exemplary flange gas channel 310 is illustrated in FIG. 3. Flange gas channels can include expansion areas 312, 314 and respective outlets 316, 318, which terminate at opposite sides of the flange and adjacent each other. For example, the first gas channels, corresponding to first gas streams, can terminate at a first side 296 of flange 293 and the second gas channels, corresponding to second gas streams, can terminate at a second side 298 of flange 292.

Gas injection system 200 can optionally include a moisture sample panel. A moisture sample panel can include, for example, one or more pressure transducers, pneumatic valves, and/or restrictors. An exemplary moisture sample panel is disclosed in U.S. application Ser. No. 15/997,445, filed Jun. 4, 2018, and entitled GAS DISTRIBUTION SYSTEM AND REACTOR SYSTEM INCLUDING SAME, the relevant contents of which are hereby incorporated herein by reference, to the extent such contents do not conflict with the present disclosure.

Reaction chamber 290 can be formed of, for example, quartz. Exemplary operating pressures within reaction chamber 290 during substrate processing can range from, for example, about 0.5 mTorr to about 780 Torr. By way of examples, the pressure can range from about 2 mTorr to about 780 Torr. In accordance with exemplary embodiments of the disclosure, system 200 can provide desired, stable, independent flow control within each channel over such pressure ranges.

Controller 294 can be configured to perform various functions and/or steps as described herein. Controller 294 can include one or more microprocessors, memory elements, and/or switching to perform the various functions. Although illustrated as a single unit, controller 294 can alternatively comprise multiple devices. By way of examples, controller 294 can be used to control flow of gas from first gas source 203 and/or second gas source 205 in a plurality of gas channels, which can span between, for example, respective first or second gas outlets, optionally through flange 292, and optionally to reaction chamber 290. Controller 294 can be configured to provide open-loop and/or closed-loop flow control using, for example, the same hardware. In particular, controller 294 can be configured to provide desired ratios of a total flow of a respective gas (e.g., from first gas source 203 or second gas source 205) in each of the channels coupled to the respective sources. In accordance with various examples of the disclosure, controller 294 includes proportional-integral-derivative (PID) controllers, which allow independent, closed-loop control of the various controllable valves described herein, including gas valves 250-268. With PID closed-loop control, system 200 can dynamically adjust flows in one or more (e.g., all) gas channels to set points and/or provide stable, especially initial, flow rates of gases to reaction chamber 290 when switching between gas sources and/or when the operating pressure is relatively high (e.g., near atmospheric pressure). The closed-loop control allows for automatic and stable control of flow rates through each channel over a wide variety of pressure ranges, such as those set forth herein. The closed-loop control further allows for control without tool matching, which is often required for traditional systems. By way of example, using PID control, an initial set point for each controlled valve can be selected. Flow ratio feedback from an output of each flow sensor coupled to the controllable valve can then be used in connection with a PID controller of controller 294 to control the desired set point (i.e., flow ratio) of each of the controlled valves.

Systems and methods described herein improved the concentration profile of a dopant within a film deposited using the systems and/or methods. In accordance with examples of the disclosure, a non-uniformity of a concertation of a dopant from center to edge of the substrate varied less than 10%, less than 7.5%, and less than 6%-even with the relatively high concentrations of dopant.

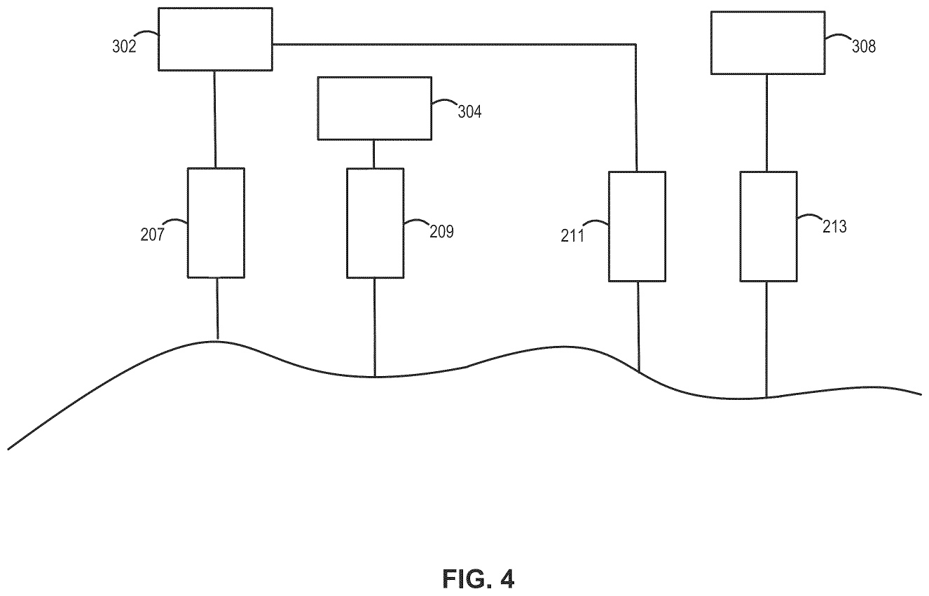

As noted above, in accordance with at least one embodiment of the disclosure, first gas inlet 202 can receive a first gas comprising a first precursor and a dopant source, and second gas inlet 204 can receives a second gas comprising the first precursor or a second precursor and an etchant. In this case, gas source 302 can include a precursor as described herein, gas source 304 can include a dopant source as described herein, gas source 306 can be or include gas source 302 or another (e.g., second) precursor gas source, and gas source 308 can include an etchant. FIG. 4 illustrates an example of a shared gas source 302. Flow controllers 207 and 211 are coupled to shared gas source 302. When gas sources 302 and 306 are the same/shared source, a gas ratio between first gas source 203 and second gas source 205 can vary from, for example, about 0.8 to about 0.9, about 0.9 to about 1.0, or about 1.0 to about 1.3.

In accordance with other examples of the disclosure, first gas inlet 215 can receive a first gas comprising an etchant and a dopant source, and second gas inlet 217 can receive a second gas comprising a precursor. In this case, gas source 302 can include an etchant as described herein, gas source 304 can include a dopant source as described herein, gas source 306 can include a precursor source as described herein, and gas source 308 can include a carrier gas. In this case, a flowrate of the carrier gas and the precursor gas can each be independently controlled to provide additional control over the composition films deposited.

In various embodiments, the systems and methods herein may mitigate against undesired effects to a film toward the edge of a substrate (e.g., edge roll-down), as well as improve the desired germanium concentration in the film. For example, including a compound common to both the first gas and the second gas (e.g., having a common precursor and/or etchant between the first gas from first gas source 203 and the second gas from second gas source 205) during substrate processing may achieve beneficial results. As a further example, first gas source 203 and second gas source 205 may both comprise and deliver hydrogen chloride and/or germane to reaction chamber 290.

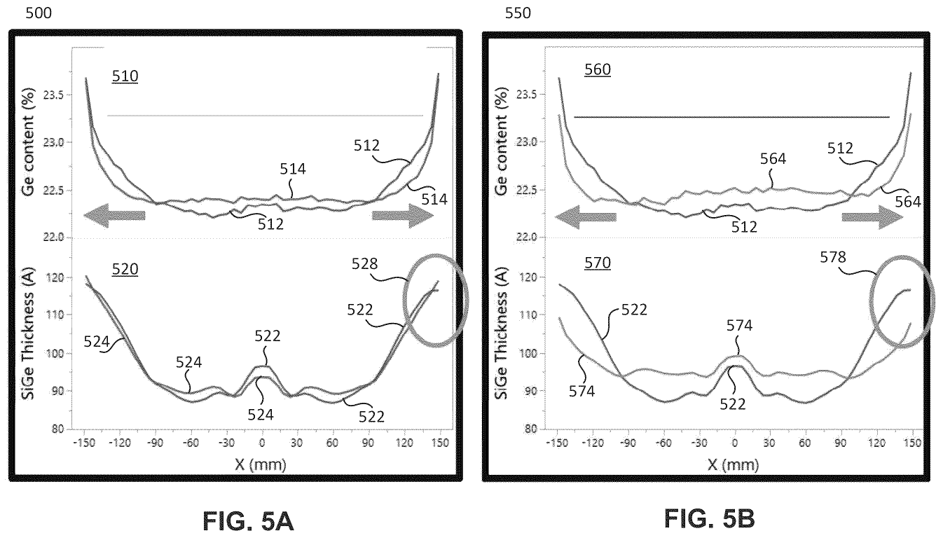

With reference to Table 1 and FIGS. 5A-5C, four examples of the disclosure are described, in which gases comprising various components being sent through the first gas source and the second gas source of a reactor system (e.g., first gas source 203 and second gas source 205 shown in FIG. 2), which were compared with one another. In the example depicted by data sets 512, 522, the first gas and the second gas do not have a component in common, while in the other three experiments, the first gas comprises a component in common with the second gas. Data sets 512 and 522 are shown in all three charts 500, 550, and 600. The top plot in each chart (top plots 510, 560, and 610) shows the germanium content in a silicon germanium layer deposited on a substrate as a function of the position on the substrate (the “0” position on the x-axis indicates the middle of the substrate, and moving along the x-axis in either direction indicates moving from the substrate center toward the substrate edge(s)). The bottom plot in each chart (bottom plots 520, 570, and 620) shows the thickness of the silicon germanium layer deposited on the substrate as a function of the position on the substrate (same x-axis units as for the top plots).

TABLE 1

| | | Gas | Gas | Flow Ratio Through | | | | |
|---|---|---|---|---|---|---|---|---|
| Data Set | Gas | Flow | Source | Gas Outlets | | | | |
| 512, 522 | GeH₄, SiH₄ | | First | 30 | 9 | 22 | 9 | 30 |
| | HCl | | Second | 15.5 | 23 | 23 | 23 | 15.5 |
| 514, 524 | GeH₄, SiH₄, HCl | 59% | First | 30 | 9 | 22 | 9 | 30 |
| | HCl | 41% | Second | 1 | 1 | 96 | 1 | 1 |
| 564, 574 | GeH₄, SiH₄, HCl | 59% | First | 30 | 9 | 22 | 9 | 30 |
| | HCl | 41% | Second | 1 | 1 | 96 | 1 | 1 |
| 614, 624 | GeH₄, SiH₄, HCl | 58.30% | First | 30 | 9 | 22 | 9 | 30 |
| | GeH₄ | 41.70% | Second | 48.5 | 1 | 1 | 1 | 48.5 |

As shown in Table 1, data sets 512 and 522 show the results of flowing a first gas comprising germane (GeH₄) and silane (SiH₄) through a first gas source, and flowing a second gas comprising hydrogen chloride (HCl) through a second gas source to a reaction chamber. The “Gas Flow” column of Table 1 indicates the percentage of total gas flow (the total gas flow being the sum of the first gas flow and the second gas flow) made up by of each of the first gas and the second gas. For example, for data sets 514 and 524, the total gas flow between the first gas and the second gas comprises 59% first gas and 41% second gas. Furthermore, in these examples, the first and second gas sources each have five gas outlets (e.g., gas outlets 210-228 shown in FIG. 2). Accordingly, the “Flow Ratio Through Gas Outlets” column and sub-columns indicate the percentage of each gas flowed through each gas outlet. For example, for the first gas of data sets 512, 522, 30% of the first gas was flowed through each of the two outermost gas outlets (i.e., the gas outlets most proximate the edge of the substrate), 9 percent of the first gas was flowed through each of two inner gas outlets, and 22 percent of the first gas was flowed through a center gas outlet. Similarly, for the second gas of data sets 512, 522, 15.5% of the second gas was flowed through each of two outermost gas outlets (i.e., the gas outlets most proximate the edge of the substrate), 23 percent of the second gas was flowed through each of two inner gas outlets, and 23 percent of the second gas was flowed through a center gas outlet. The flow rate and/or flow amount of a gas through any of the gas outlets in a gas source, as discussed herein, may be adjusted independently or in conjunction with other gas outlets (e.g., via a respective gas valve 250-268, as shown in FIG. 2).

As can be seen by data set 512, the germanium content in the silicon germanium layer gradually begins to increase from a relatively constant germanium content around 85 millimeters from the center of the substrate. A more desired germanium content configuration in a silicon germanium layer may be one that is relatively constant on the substrate for a long as possible spanning out from the substrate center, and then a sharp increase proximate the substrate edge (thus having a more consistent germanium content in the silicon germanium layer across a greater area of the substrate before a sharp increase near the substrate edge). As can be seen by data set 522 (and emphasized by windows 528, 578, and 628), the silicon germanium layer thickness increases toward the edge of the substrate and then tapers as the rate of increasing layer thickness decreases (i.e., edge roll-down). This thickness pattern of a silicon germanium layer may be less desirable than a layer thickness that continues to increase toward the substrate edge and does not taper.

Charts 500 and 550, and data sets 514, 524 and 564, 574, shown in Table 1 and in FIGS. 5A and 5B, respectively, depict the results of flowing a first gas comprising germane, silane, and HCl through a first gas source, and flowing a second gas comprising HCl through a second gas source to a reaction chamber. Therefore, the first gas and the second gas both comprise HCl. The flow percentages and the flow ratio through each gas outlet are shown in the respective columns of Table 1. The example producing data sets 514, 524 comprised a silicon controlled rectifier (SCR) having a top-biased power ratio of 55% top/45% bottom, while the example producing data sets 564, 574 comprised an SCR having a bottom-biased power ratio of 42% top/58% bottom. As can be seen through data sets 514 and 564, the germanium content in the resulting silicon germanium layers gradually begins to increase from a relatively constant germanium content around 110 millimeters from the center of the substrate. Thus, including a common compound in both the first and second gases (e.g., an etchant, such as HCl) resulted in a more consistent germanium content in the silicon germanium layer across a greater area of the substrate than that shown in data set 512. As can be seen through data sets 524 and 574 (and emphasized by windows 528 and 578), the silicon germanium layer thickness continually increases toward the edge of the substrate without tapering (i.e., without edge roll-down). Thus, providing these first and second gases, both sharing at least one compound (e.g., HCl), produced more desirable characteristics of the resulting silicon germanium layer than that shown in data set 522.

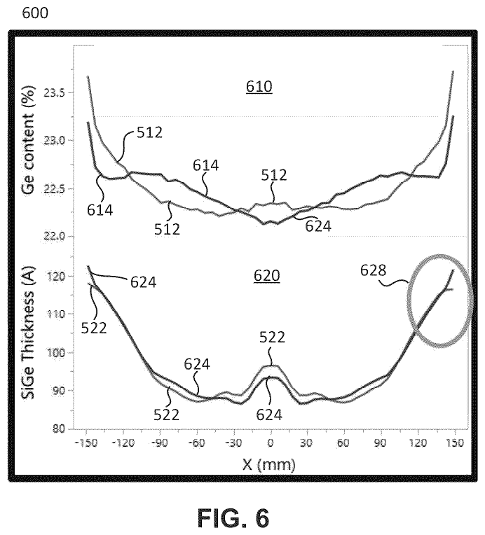

Chart 600, and data sets 614, 624, shown in Table 1 and in FIG. 6, depict the results of flowing a first gas comprising germane, silane, and HCl through a first gas source, and flowing a second gas comprising germane through a second gas source to a reaction chamber. Therefore, the first gas and the second gas both comprise germane. The flow percentages and the flow ratio through each gas outlet are shown in the respective columns of Table 1. As can be seen through data set 614, the germanium content in the resulting silicon germanium layer gradually begins to increase from a relatively constant germanium content around 120 millimeters from the center of the substrate. Thus, including a common compound in both the first and second gases (e.g., a precursor, such as germane) resulted in a more consistent germanium content in the silicon germanium layer across a greater area of the substrate than that shown in data set 512. As can be seen through data set 624 (and emphasized by window 628), the silicon germanium layer thickness continually increases toward the edge of the substrate without tapering (i.e., without edge roll-down). Thus, providing these first and second gases, both sharing at least one compound (e.g., germane) produced more desirable characteristics of the resulting silicon germanium layer than that shown in data set 522.

Although exemplary embodiments of the present disclosure are set forth herein, it should be appreciated that the disclosure is not so limited. For example, although the gas injection and reactor systems are described in connection with various specific configurations, the disclosure is not necessarily limited to these examples. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

We claim:

1. A method, comprising:
flowing a first gas through a first gas manifold comprising a first gas inlet and a plurality of first gas outlets;
flowing a second gas through a second gas manifold comprising a second gas inlet and a plurality of second gas outlets, wherein the first gas and the second gas comprise a common component;
controlling the first gas flowing through each of the plurality of first gas outlets via a mass flow controller coupled to each of the plurality of first gas outlets;
controlling the second gas flowing through each of the plurality of second gas outlets via a mass flow controller coupled to each of the plurality of second gas outlets;
flowing the first gas and the second gas into a reaction chamber in fluid communication with the first gas manifold and the second gas manifold; and
depositing a material on a surface of a substrate in the reaction chamber.

2. The method of claim 1, wherein the common component comprised in both the first gas and the second gas is hydrogen chloride.

3. The method of claim 2, wherein the first gas further comprises a silicon-containing compound.

4. The method of claim 3, wherein the first gas further comprises a germanium-containing compound.

5. The method of claim 4, wherein silicon-containing compound comprised in the first gas is silane.

6. The method of claim 5, wherein germanium-containing compound comprised in the first gas is germane.

7. The method of claim 1, wherein the common component comprised in both the first gas and the second gas is a germanium-containing compound.

8. The method of claim 7, wherein the wherein the common component comprised in both the first gas and the second gas is germane.

9. The method of claim 7, wherein the first gas further comprises a silicon-containing precursor.

10. The method of claim 9, wherein the first gas further comprises an etchant.

11. The method of claim 10, wherein the silicon-containing precursor comprised in the first gas is silane and the etchant is hydrogen chloride.

12. The method of claim 1, further comprising rotating the susceptor.

13. The method of claim 12, wherein the susceptor is rotated at a rotational speed of about 60 to about 30, about 30 to about 15, or about 15 to about 5 rotations per minute

14. A method, comprising:
flowing a first gas to a reaction chamber through a plurality of first gas outlets;
flowing a second gas to the reaction chamber through a plurality of second gas outlets, wherein the first gas and the second gas comprise a common component;
a controller configured to control an amount of the first gas and the second gas flowing to the reaction chamber, wherein the controller is configured to flow a different amount of the first gas than an amount of the second gas; and
depositing a material on a surface of a substrate in the reaction chamber.

15. The method of claim 14, further comprising:
controlling, via the controller, a first gas valve coupled to each of the first gas outlets; and
controlling, via the controller, a second gas valve coupled to each of the second gas outlets.

16. The method of claim 14, wherein the common component comprised in both the first gas and the second gas is at least one of hydrogen chloride or germane.

17. The method of claim 16, wherein the first gas comprises a silicon-containing compound, hydrogen chloride, and germane.

18. A method, comprising:
flowing a first gas to a reaction chamber through multiple sets of first gas outlets, wherein each set of first gas outlets comprises at least one first gas outlet, and wherein the multiple sets of first gas outlets comprises a first center set positioned closest to a center of a substrate, and a first outer set positioned closer to an edge of the substrate than the first center set;
flowing a second gas to the reaction chamber through multiple sets of second gas outlets, wherein each set of second gas outlets comprises at least one second gas outlet, and wherein the multiple sets of second gas outlets comprises a second center set positioned closest to the center of a substrate, and a second outer set positioned closer to the edge of the substrate than the second center set,
wherein the first gas and the second gas comprise a common component;
wherein a controller is configured to control an amount of the first gas and the second gas flowing to the reaction chamber, wherein the amount of the first gas flowing through the first center set is different than the amount of the first gas flowing through the first outer set, and wherein the amount of the second gas flowing through the second center set is different than the amount of the second gas flowing through the second outer set; and
depositing a material on a surface of a substrate in the reaction chamber.

19. The method of claim 18, wherein the common component comprised in both the first gas and the second gas is at least one of hydrogen chloride or germane.

20. The method of claim 19, wherein the first gas comprises a silicon-containing compound, hydrogen chloride, and germane, and wherein the second gas comprises hydrogen chloride or germane.
